(19) United States
(12) Patent Application Publication
(10) Pub. No.: US 2022/0362868 A1
(43) Pub. Date: Nov. 17, 2022

(54) METHOD FOR COATING TEETH OF A CUTTING TOOL

(71) Applicant: The M.K. Morse Company, Canton, OH (US)

(72) Inventors: Chandra Sekhar Rakurty, Canton, OH (US); Matthew J. Morelli, Homeworth, OH (US); Joseph A. Tarr, East Canton, OH (US)

(21) Appl. No.: 17/765,636

(22) PCT Filed: Oct. 12, 2020
(86) PCT No.: PCT/US20/55224

§ 371 Date: Mar. 31, 2022

Related U.S. Application Data
(60) Provisional application No. 62/913,699, filed on Oct. 10, 2019.

(51) Int. Cl. B23D 65/00; B23K 1/00; B24B 3/36

(52) U.S. Cl. CPC B23D 65/00; B23K 1/0008; B24B 3/36; C23C 14/0605

(57) ABSTRACT

A method of manufacturing a saw blade includes placing at least one tooth in an holder where at least one face of the tooth is covered and at least one face of the tooth is exposed, coating the exposed face, and after the coating, joining the tooth to a blade backer at an uncoated face.

### CROSS-REFERENCE TO RELATED APPLICATIONS

This application claims priority to and the benefit of U.S. Provisional Patent Application No. 62/913,699, filed 10 Oct. 2019, the contents of which are hereby incorporated by reference in their entirety.

### BACKGROUND

This relates in general to cutting tools. One type of cutting tools are saw blades. There are many types of saw blades including, circular saw blades, reciprocating saw blades, and band saw blades, among others.

There are several different manufacturing or treatment processes to which these blades may be subjected. For example, a blade may be subjected to heat treating and/or coating. These processes may change several properties of the blades, such as wearability, ductility, hardness, and shape, among others.

### SUMMARY

This relates more particularly to a method for coating the teeth of a cutting tool, and the resulting tool.

A method of manufacturing a saw blade includes placing at least one tooth in an holder where at least one face of the tooth is covered and at least one face of the tooth is exposed, coating the exposed face, and after the coating, joining the tooth to a blade backer at an uncoated face.

The resulting saw blade may thus include teeth with coated and uncoated faces.

Various aspects will become apparent to those skilled in the art from the following detailed description and the accompanying drawings.

### BRIEF DESCRIPTION OF THE DRAWINGS

FIG. 1 is a schematic view of a tooth tip with a coated face.

### DETAILED DESCRIPTION

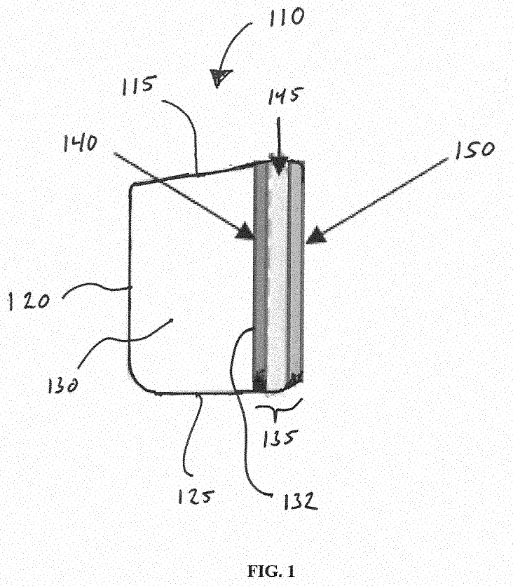

The following is described in conjunction with FIG. 1. A cutting tooth 110 includes a top face 115. In the illustrated embodiment the top face 115 is formed as a clearance face. The tooth 110 includes a back face 120 and a bottom face 125. In the illustrated embodiment the back face 120 and the bottom face 125 are prepared for joining to a blade backer (not shown) with either or both of the back face 120 and/or the bottom face 125 being bonded to the blade backer, for example by welding, brazing, bonding or other suitable process. The tooth 110 also includes side faces (one shown) 130.

The cutting tooth 110 includes a front face 132. In the illustrated embodiment the front face 132 is formed as a rake face and includes a coating 135 having bonding layer 140, a heat resistant layer 145 and a tool ware layer 150, though not all such layers are required.

In a method of manufacturing a saw blade, at least one tooth 110 is placed in an holder (not shown) where at least one face of the tooth is covered and at least one face of the tooth is exposed. In an exemplary method, the tooth 110 is disposed in a pocket in the holder where the top face 115, the back face 120, the bottom face 125 and the side faces 130 are covered, and the front face 132 is exposed for coating.

During the preferred coating process, the bonding layer 140 is placed on the front face 132, the heat resistant layer 145 is then placed on the bonding layer 140, and then the tool wear layer 150 is placed upon the heat resistant layer 145.

While the above is preferred, it must be understood that the exposed face(s) to be coated may be the front face 132 or any other face or faces as desired, and that any face or faces may be covered during the coating process in any number and types of layers as desired.

Thus, in at least one embodiment, the coating process results in multi-layer coatings upon at least one face of a cutting tooth.

The coating process may utilize a high temperature coating process, such as Chemical Vapor Deposition (CVD), Physical Vapor Deposition (PVD), diamond or diamond-like coating processes and others.

After the coating process the tooth 110 may be joined to the blade backer.

The method may include brazing, welding, or bonding an uncoated face, such as the back face 120 or bottom face 125, to the blade backer. The blade backer may have a tooth seat formed therein for mating with the back face 120 and/pr bottom face 125.

Thus, a coating or coatings may be applied to select faces of a tooth before the tooth is joined to a blade backer. Other tooth faces may then be brazed, welded, or bonded to a blade backer after the coating process.

The method may further include grinding the coated or uncoated faces before or after joining the tooth to the blade backer.

While principles and modes of operation have been explained and illustrated with regard to particular embodiments, it must be understood, however, that this may be practiced otherwise than as specifically explained and illustrated without departing from its spirit or scope.

1. A method of manufacturing a saw blade comprising:
placing at least one tooth in an holder where at least one face of the tooth is covered and at least one face of the tooth is exposed,
coating the exposed face, and
after the coating, joining the tooth to a blade backer.

2. The method of claim 1 where the at least one covered face includes a back face.

3. The method of claim 2 where the joining includes brazing the back face to the blade backer.

4. The method of claim 2 where the joining includes welding the back face to the blade backer.

5. The method of claim 2 where the joining includes bonding the back face to the blade backer.

6. The method of claim 2 further comprising:
prior to the joining, grinding the back face.

7. The method of claim 1 where the at least one covered face includes a bottom face.

8. The method of claim 7 where the joining includes brazing the bottom face to the blade backer.

9. The method of claim 7 where the joining includes welding the bottom face to the blade backer.

10. The method of claim 7 where the joining includes bonding the bottom face to the blade backer.

11. The method of claim 7 further comprising:
prior to the joining, grinding the bottom face.

12. The method of claim 1 where the at least one exposed face includes a front face.

13. The method of claim 12 where the coating process results in multi-layer coatings on the front face.

14. The method of claim 13 where the front face forms a rake face.

15. The method of claim 1 where the coating process utilizes a high temperature coating process.

16. The method of claim 15 where the high temperature coating process includes Chemical Vapor Deposition.

17. The method of claim 15 where the high temperature coating process includes Physical Vapor Deposition.

18. The method of claim 15 where the high temperature coating process includes a diamond or diamond-like coating process.
